(19) United States
(12) Patent Application Publication
(10) Pub. No.: US 2007/0007862 A1
(43) Pub. Date: Jan. 11, 2007

(54) Ultrasonic vibrator and ultrasonic flowmeter employing the same

(76) Inventors: Akihisa Adachi, OSAKA (JP); Masato Sato, Nara (JP); Masahiko Hashimoto, Osaka (JP)

Correspondence Address: WENDEROTH, LIND & PONACK L.L.P., 2033 K. STREET, NW, SUITE 800, WASHINGTON, DC, 20006, US

(21) Appl. No.: 10/569,385

(22) PCT Filed: Sep. 17, 2004
(86) PCT No.: PCT/JP04/13617

§ 371 Date: Feb. 24, 2006

(30) Foreign Application Priority Data
Sep. 18, 2003 (JP) 2003-325808

(51) Int. Cl. H01L 41/053

(52) U.S. Cl. 310/348

(57) ABSTRACT

A difference in the thermal expansion coefficient between a casing and a piezoelectric body is adapted to be reduced by making an adhesive expand and contract, and this can prevent the separation of connection between the casing and the piezoelectric body and the damage of the piezoelectric body. As a result, the ultrasonic vibrator can be used over an extended period of time in an outdoor use environment.

### DESCRIPTION

Ultrasonic vibrator and ultrasonic flowmeter employing the same

1. Technical Field

The present invention relates to an ultrasonic vibrator capable of measuring the flow rate and the flow velocity of a gas or a liquid by means of ultrasonic waves and an ultrasonic flowmeter that employs the vibrator.

2. Background Art

Conventionally, as an ultrasonic vibrator for use in an ultrasonic flowmeter of the kind, a piezoelectric ceramic 1 has been brazed to a metal diaphragm 2 with a brazing material 3 as shown in FIG. 7 (refer to Japanese Unexamined Patent Publication No. H04-309817 A).

### DISCLOSURE OF INVENTION

Ultrasonic flowmeters are sometimes used as gas/liquid flow rate monitors of various plants or as domestic gas meters and sometimes installed outdoors in these cases. When an ultrasonic flowmeter is installed outdoors, the device temperature, which is 20° C. to 25° C. before dawn, rises in a short time with sunrise particularly in summer, and the temperature of the device itself easily rises to a temperature of 60° C. to 70° C. in an installation condition exposed to direct sunlight. Also, when the device is installed in a cold district below a temperature of not higher than −20° C. in winter, a temperature rise of several tens of degrees centigrade easily occurs under exposure to direct sunlight. FIG. 8 shows one example of the temperature change in a day of an ultrasonic flowmeter installed in an outdoor environment. The ultrasonic flowmeter is required to have a stable measurement performance over an extremely extended period of time with respect to a temperature change, and, for example, a domestic gas meter desirably operates maintenance free for ten years.

In particular, durability to the temperature change of an ultrasonic vibrator, which is a principal device of the ultrasonic flowmeter, has great importance for the whole measurement system. The ultrasonic vibrator is generally constituted by integrating a piezoelectric body with its casing and other components by bonding or joining the vibrator to the casing and other components as in the conventional construction, and the construction of the bonded portion or the joined portion is the principal factor that determines the durability of the device to the temperature change. As a method for evaluating the factor, a thermal load repeating test (hereinafter referred to as a thermal shock test) is carried out. The test repeats applying each of thermal loads at temperatures of, for example, 80° C. and −40° C. every 30 minutes to the ultrasonic vibrator.

However, since the piezoelectric ceramic 1 has been brazed to the metal diaphragm 2, the conventional construction has had the issue that the bonded portion of the metal diaphragm 2 and the piezoelectric ceramic 1 has separated from each other or the piezoelectric ceramic 1 has been damaged when subjected to the thermal load repeating test (hereinafter referred to as the thermal shock test) due to a difference in the thermal expansion coefficient between the metal diaphragm 2 and the piezoelectric ceramic 1.

An object of the present invention is to provide an ultrasonic vibrator that is capable of bonding endurable to a thermal shock test and excellent in reliability and an ultrasonic flowmeter that employs the vibrator.

According to the present invention, there is provided an ultrasonic vibrator comprising:
a piezoelectric body;
an adherend fixation body constituted by a metallic lidded cylindrical casing having a ceiling portion and a sidewall portion; and
an adhesive for fixing the piezoelectric body to an inner wall surface of the ceiling portion of the adherend fixation body, the adhesive having a linear expansion reducing function to expand and contract so as to reduce a difference in linear expansion coefficient between the piezoelectric body and the adherend fixation body.

Therefore, the conventional issue can be solved, and the ultrasonic vibrator of the present invention can reduce a difference in the linear expansion coefficient between the piezoelectric body and the adherend fixation body by making an adhesive used for fixation between the piezoelectric body and the adherend fixation body expand and contract.

Moreover, the ultrasonic vibrator of the present invention becomes able to prevent the separation at the bonded portion of the piezoelectric body and the adherend fixation body and the damage of the piezoelectric body due to the thermal shock test, and the ultrasonic vibrator can be used over an extended period of time even in an outdoor environment.

Moreover, according to the present invention, there is provided an ultrasonic flowmeter comprising:
a flow rate measurement unit for measuring a flow rate of a flowing fluid to be measured;
a pair of ultrasonic vibrators, which are defined in the present invention, provided at the flow rate measurement unit, for transmitting and receiving ultrasonic waves to and from the fluid to be measured;
a measurement unit for measuring a propagation time between the pair of ultrasonic vibrators; and
a flow rate calculation part for calculating the flow rate of the fluid to be measured on a basis of a signal from the measurement unit.

### BRIEF DESCRIPTION OF DRAWINGS

These and other aspects and features of the present invention will become clear from the following description taken in conjunction with the preferred embodiments thereof with reference to the accompanying drawings, in which:

FIG. 1 is a sectional view of an ultrasonic vibrator of a first embodiment of the present invention;

FIG. 2 is a perspective view of a piezoelectric body, to which an adhesive is applied, of the ultrasonic vibrator of the first embodiment of the present invention;

FIG. 3 [(a), (b), (c), (d), (e), (f), and (g)] is a manufacturing process view of the ultrasonic vibrator of the first embodiment of the present invention;

FIG. 4 [(a), (b)] is an adhesive applying process view of the ultrasonic vibrator of the first embodiment of the present invention;

FIG. 5 [(a), (b), (c)] is an adhesive applying process view of the ultrasonic vibrator of the first embodiment of the present invention;

FIG. 6 is a structural view including a partially sectional view of an ultrasonic flowmeter that employs the ultrasonic vibrator of the first embodiment of the present invention;

FIG. 7 is a sectional view of a conventional ultrasonic vibrator;

FIG. 8 is a graph of the temperature of the ultrasonic flowmeter and time, showing one example of the temperature change in a day of the ultrasonic flowmeter installed in an outdoor environment;

FIG. 9A is a sectional view showing the state of deformation of the ultrasonic vibrator due to a temperature change from the state of normal temperature to high temperature in a comparative example in which the casing and the piezoelectric body are rigidly joined together instead of the adhesive in the ultrasonic vibrator of the first embodiment;

FIG. 9B is a sectional view showing the state of deformation due to a temperature change from the state of normal temperature to low temperature in the comparative example in which the casing and the piezoelectric body are rigidly joined together instead of the adhesive in the ultrasonic vibrator of the first embodiment;

FIG. 10A is a schematic view showing the state of thermal deformation reduction due to the deformation of the adhesive in the state of temperature change from normal temperature to high temperature;

FIG. 10B is a schematic view showing the state of thermal deformation reduction due to the deformation of the adhesive in the state of temperature change from normal temperature to low temperature;

FIG. 11A is a schematic view showing a state in which the adhesive before curing is applied to a heat-resistant polymer film by an internal strain evaluating method;

FIG. 11B is a schematic view showing a state in which the adhesive after curing by heating is applied to a heat-resistant polymer film by the internal strain evaluating method;

FIG. 12 is a graph showing a relation between the residual internal strain and H/L by the internal strain evaluating method;

FIG. 13 is a schematic view showing a state in which a sample for a tension test is set to a tension tester; and

FIG. 14 is a sectional view of the ultrasonic vibrator of the second embodiment of the present invention.

### BEST MODE FOR CARRYING OUT THE INVENTION

Before the description of the present invention proceeds, it is to be noted that like parts are designated by like reference numerals throughout the accompanying drawings.

Various aspects of the present invention are described below before describing various embodiments of the present invention with reference to the drawings.

According to the first aspect of the present invention, there is provided an ultrasonic vibrator comprising:
a piezoelectric body;
an adherend fixation body constituted by a metallic lidded cylindrical casing having a ceiling portion and a sidewall portion; and
an adhesive for fixing the piezoelectric body to an inner wall surface of the ceiling portion of the adherend fixation body, the adhesive having a linear expansion reducing function to expand and contract so as to reduce a difference in linear expansion coefficient between the piezoelectric body and the adherend fixation body. Thus, the piezoelectric body is fixed to the inner wall surface of the ceiling portion of the lidded casing with the adhesive, so that the deformation amount of the lidded casing can be reduced, and therefore, the ultrasonic vibrator of high durability to the thermal shock test can be obtained.

Therefore, the adhesive expands and contracts so as to reduce the difference in the linear expansion coefficient between the piezoelectric body and the adherend fixation body, and therefore, an ultrasonic vibrator of high durability to the thermal shock test can be obtained.

According to the second aspect of the present invention, there is provided the ultrasonic vibrator as defined in the first aspect, wherein the adhesive has a pencil hardness of H to 5B by a pencil hardness test.

According to the third aspect of the present invention, there is provided the ultrasonic vibrator as defined in the second aspect, wherein the adhesive has a height dimension ratio of not greater than approximately 5% of a warp of an end portion with respect to a center portion of the adhesive formed applied in a rectangular shape relative to a length of a long side when the adhesive is formed applied in the rectangular shape.

According to the present invention, it becomes possible to follow the behavior of the thermal stresses of the piezoelectric body and the adherend fixation body by using the adhesive of which the warp height dimension ratio is not higher than approximately 5%, and therefore, an ultrasonic vibrator of high durability to the thermal shock test can be obtained.

According to the fourth aspect of the present invention, there is provided the ultrasonic vibrator as defined in the second aspect, wherein the adhesive has an adhesive strength of 5 to 30 MPa.

According to the fifth aspect of the present invention, there is provided the ultrasonic vibrator as defined in the second aspect, wherein the adhesive has a glass transition point of 40° C. to 120° C.

According to the sixth aspect of the present invention, there is provided the ultrasonic vibrator as defined in the first aspect, wherein the adhesive has a pencil hardness of H to 5B by a pencil hardness test, a height dimension ratio of not greater than approximately 5% of a warp of an end portion with respect to a center portion of the adhesive formed applied in a rectangular shape relative to a length of a long side when the adhesive is formed applied in the rectangular shape, an adhesive strength of 5 to 30 MPa, and a glass transition point of 40° C. to 120° C.

According to the seventh aspect of the present invention, there is provided the ultrasonic vibrator as defined in any one of the first through sixth aspects, wherein the adhesive is softer than the adherend fixation body and the piezoelectric body.

According to the present invention, the adhesive, which is softer than the adherend fixation body and the piezoelectric body, is able to absorb the stress of repetitive expansion and contraction, and therefore, the ultrasonic vibrator of high durability to the thermal shock test can be obtained.

According to the eighth aspect of the present invention, there is provided the ultrasonic vibrator as defined in any one of the first through sixth aspects, wherein the adhesive is comprised of a layer of an average thickness of 2 to 3 μm.

According to the present invention, the adhesive is constructed of a thin layer of an average thickness of 2 to 3 μm, and the internal stress accumulated in the adhesive can be reduced. Therefore, the ultrasonic vibrator of high durability to the thermal shock test can be obtained.

According to the ninth aspect of the present invention, there is provided the ultrasonic vibrator as defined in any one of the first through sixth aspects, wherein the piezoelectric body has a slit formed along a thickness direction of the inner wall surface of the ceiling portion of the adherend fixation body to which the piezoelectric body is fixed.

According to the tenth aspect of the present invention, there is provided the ultrasonic vibrator as defined in any one of the first through sixth aspects, wherein the vibrator further comprises a terminal plate fixed to an open end of the lidded casing, and

the lidded casing and the terminal plate seal the piezoelectric body.

According to the present invention, the piezoelectric body and the adhesive located between the piezoelectric body and the inner wall surface of the ceiling portion of the lidded casing can be prevented from coming in contact with moisture, light, or chemical substances and so on that promote deterioration, and therefore, the ultrasonic vibrator of high durability can be obtained.

According to the eleventh aspect of the present invention, there is provided an ultrasonic flowmeter comprising:
a flow rate measurement unit for measuring a flow rate of a flowing fluid to be measured;
a pair of ultrasonic vibrators, which are defined in any one of the first through tenth aspects, provided at the flow rate measurement unit, for transmitting and receiving ultrasonic waves to and from the fluid to be measured;
a measurement unit for measuring a propagation time between the pair of ultrasonic vibrators; and
a flow rate calculation part for calculating the flow rate of the fluid to be measured on a basis of a signal from the measurement unit.

According to the present invention, the ultrasonic flowmeter, which can be used over an extended period of time even in an outdoor environment, can be obtained.

Embodiments of the present invention will be described in detail below with reference to the drawings.

### FIRST EMBODIMENT

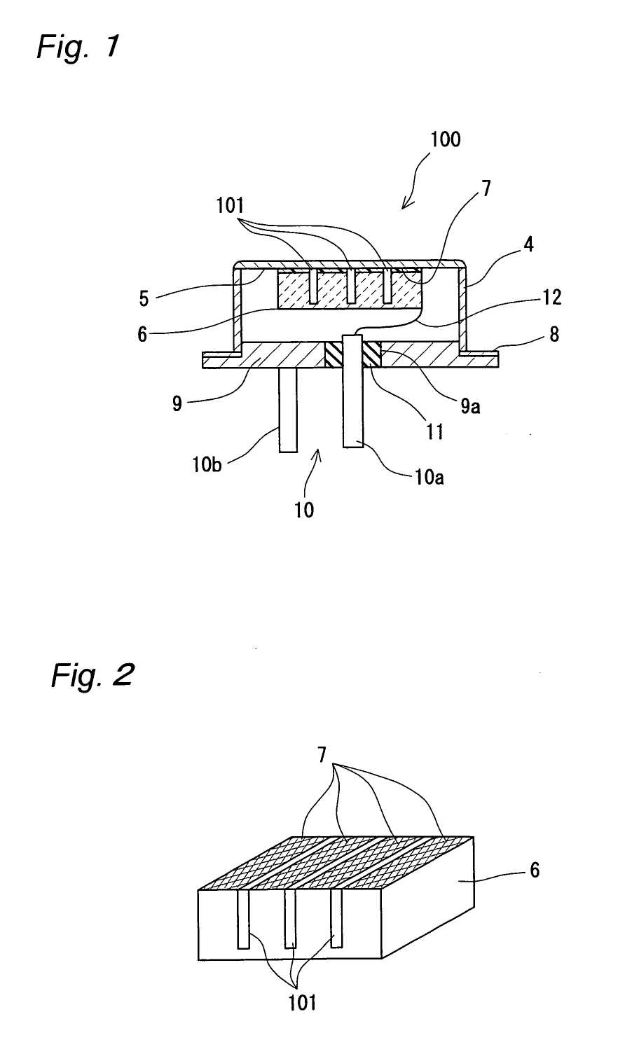

FIG. 1 shows a sectional view of the ultrasonic vibrator of the first embodiment of the present invention. FIG. 2 is a perspective view of the piezoelectric body of the ultrasonic vibrator of the first embodiment of the present invention.

In FIGS. 1 and 2, reference numeral 100 denotes an ultrasonic vibrator, 4 a flanged metallic lidded cylindrical casing of one example of the adherend fixation body, 5 an inner wall surface of the ceiling portion of the casing 4, 6 a rectangular parallelepiped piezoelectric body that has electrodes on the mutually opposite surfaces, 7 an adhesive for bonding together the inner wall surface 5 of the ceiling portion of the casing 4 and a surface of the piezoelectric body 6 on which one electrode of the electrodes is formed, 8 a casing support portion of the flange of the casing 4, 9 a terminal plate which is fitted into the opening (open end) of the casing 4 so as to seal the opening of the casing 4 and to which the casing support portion 8 of the casing 4 is fixed, 10 outer terminals for making electric continuity to the piezoelectric body 6, 10a a signal outer terminal electrically connected to the other electrode of the piezoelectric body 6 penetrating a through hole 9a of the terminal plate 9, 10b a grounding outer terminal electrically connected to the terminal plate 9, 11 an insulating portion that is placed so as to be filled in the through hole 9a of the terminal plate 9 to prevent short circuit between the casing 8 and the terminal plate 9 and the signal outer terminal 10a, 12 a signal cable for making electric continuity between the signal outer terminal 10a and the other electrode of the piezoelectric body 6, and 101 slits that extend from an electrode surface on which the one electrode of the piezoelectric body 6 is formed along the direction of the thickness perpendicular to the electrode surface and are formed at regular intervals for vibration mode control. In the example, three slits 101 are provided.

The detail of the structure of the ultrasonic vibrator 100 is described with reference to FIGS. 1 and 2.

As one example, the casing 4 is constituted of lidded cylinder of stainless steel, the piezoelectric body 6 is constituted of piezoelectric ceramics, the terminal plate 9 is constituted of iron, and the adhesive 7 is constituted of a thermosetting epoxy based resin. The casing 4 and the piezoelectric body 6 are connected to each other by the adhesive 7, and one electrode is formed by, for example, baking silver or sputtering, on the adhesion surface of the piezoelectric body 6. The casing 4 and the electrode surface of the piezoelectric body 6 are bonded together with the adhesive 7. At the same time, by forming the adhesive 7 so that the adhesive 7 comes to have a thickness dimension equivalent to the surface roughness of the casing 4 and the electrode surface of the piezoelectric body 6, numbers of points of contact between the casing 4 and the electrode surface of the piezoelectric body 6 are formed, securing electric continuity between both the members. The casing 4 has electric continuity to the grounding outer terminal 10b via the casing support portion 8 and the terminal plate 9. On the other hand, the electrode opposite from the adhesion surface of the piezoelectric body 6 is connected to the signal outer terminal 10a via the signal cable 12. Both the signal outer terminal 10a and the grounding outer terminal 10b are provided at the terminal plate 9, and the signal outer terminal 10a is fixed to the terminal plate 9 via the insulating portion 11 in order to prevent the electrical short circuit.

The piezoelectric body 6 is provided with the slits 101 for controlling the vibration mode. As shown in FIG. 2, the slits 101 are constructed by dividing the adhesion surface (grounding electrode surface) (see the cross-hatched portions of FIG. 2) to the casing 4 into four identical rectangular regions. The slits 101 are each constructed so as to divide the piezoelectric body 6 while being formed in the direction of the depth of the piezoelectric body 6 (the direction of the depth of the inner wall surface of the ceiling portion of the casing 4 to which the piezoelectric body 6 is fixed) by not less than 60% and ideally not less than 80%. This arrangement is for the reasons as follows. Normally, the dimension in the direction of the thickness of the piezoelectric body 6 is set one half of the wavelength of the ultrasonic waves at the frequency used, the wavelength served as a reference dimension. Ultrasonic waves resonate in the thickness direction (longitudinal vibration mode) when the dimension in the widthwise direction of the piezoelectric body 6 becomes equal to or greater than the wavelength. However, ultrasonic waves propagate also in the widthwise direction and reflects on the side surfaces of the piezoelectric body 6 in relation to the Poisson's ratio (expansion and contraction in the thickness direction induce expansion and contraction in the widthwise direction) thereby producing a complicated vibration mode in the widthwise direction and obstructing the longitudinal vibration mode. In the case of resonation in the thickness direction, a portion in the vicinity of the center of the thickness receives the greatest influence of the Poisson's ratio. Therefore, division by at least not less than 60% is necessary beyond the center. In order to ideally make the propagation in the widthwise direction almost zero, the division is required to be not less than 80%.

With the thus-structured slits 101, an increase in the efficiency of the excitation in the longitudinal vibration mode for radiating and receiving sonic waves is achieved, and the unnecessary transverse vibration mode is suppressed. By thus constituting the slits 101, a low-voltage driving becomes possible, and, when the ultrasonic vibrator is used for, for example, a domestic gas meter, a gas meter that is maintenance free for ten years operating on a battery can be provided.

### OPERATION OF ULTRASONIC VIBRATOR

The operation of the ultrasonic vibrator 100 of the above construction is described below.

Driving vibrations are applied from the signal outer terminal 10a to the ultrasonic vibrator 100. As the driving signal, burst waves that include frequencies in the vicinity of the resonance frequency of the piezoelectric body 6 are often used, and vibrations at the resonance frequency are excited at the piezoelectric body 6 by the driving signal. In the piezoelectric body 6, the excitation of unnecessary transverse combination vibration is suppressed by the effect of the slits 101, and longitudinal vibrations whose vibration direction is orthogonal to the sonic wave radiation direction are highly efficiently excited. By the generated mechanical vibrations, ultrasonic waves are transmitted via the adhesive 7 and the casing 4 into the liquid or gas that faces the casing 4. During wave reception, the sonic waves, which arrive via the casing 4 and the adhesive 7, are transmitted to the piezoelectric body 6, and mechanical vibrations are excited in the piezoelectric body 6. By the excited mechanical vibrations, a voltage is generated between the mutually opposing electrodes of the piezoelectric body 6 and becomes a reception wave signal, which is processed by being transmitted to and processed in, for example, the measurement unit and the flow rate calculation part of an ultrasonic flowmeter via the signal cable 12 and the signal outer terminal 10a.

### SELECTION OF HARDNESS BY DIFFERENCE IN LINEAR EXPANSION COEFFICIENT

As one example, when the ultrasonic flowmeter is constituted of the casing 4 of stainless steel and the piezoelectric body 6 of piezoelectric ceramic of the PZT (lead zirconate titanate) system, the linear expansion coefficient of the casing 4 becomes about 17.8 ppm/° C., and the linear expansion coefficient of the piezoelectric body 4 becomes about 7.8 ppm/° C. within a temperature range in which the ultrasonic flowmeter is used outdoors, meaning that the linear expansion coefficient of the casing 4 becomes greater than that of the piezoelectric body 6 by 50% or more. Therefore, in order to stably operate the ultrasonic vibrator of the first embodiment of the present invention and the ultrasonic flowmeter that employs the vibrator over an extended period of time in an outdoor environment, selection of the adhesive 7 that is interposed between the casing 4 and the piezoelectric body 6 and connects both of them is important.

Since the piezoelectric body 6 of the first embodiment of the present invention has the slits 101 in the direction of vibration for the purpose of increasing the efficiency of excitation in the longitudinal vibration mode, it cannot be avoided that the strength in the vicinity of the adhesion surface to the casing 4 and the strength of the common portion that joins the columnar structures divided by the slits 101 are degraded in comparison with the ordinary bulk state (in other words, the rectangular parallelepiped state with no slit). Therefore, the selection of the adhesive 7 becomes more important than when the normal piezoelectric body in the bulk state is employed.

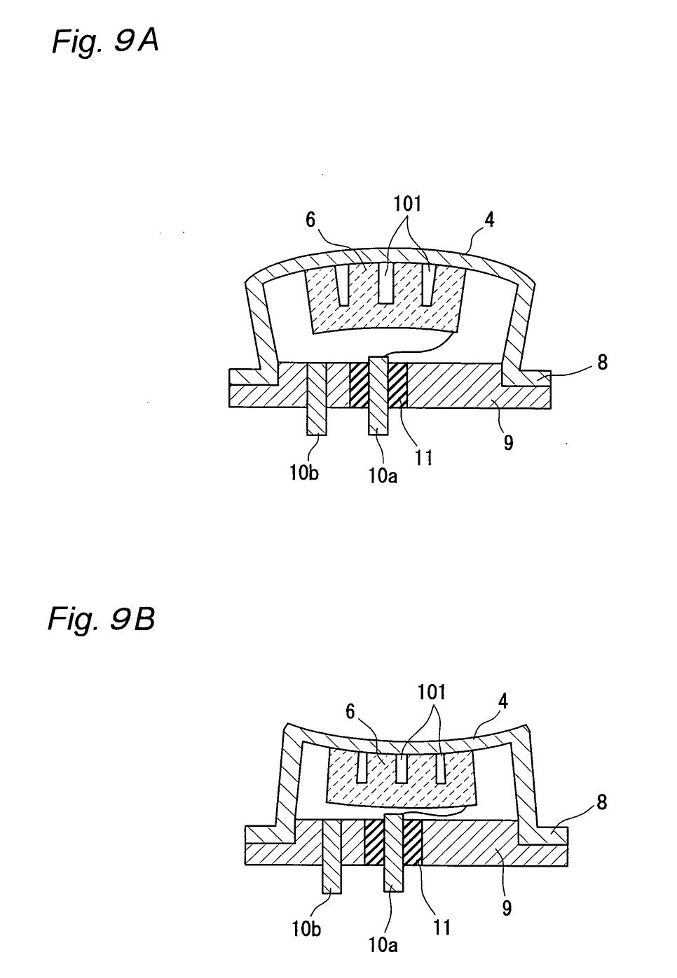

FIGS. 9A and 9B show the states of deformation of the ultrasonic vibrator 100 due to temperature changes in the case of the comparative example in which the casing 4 and the piezoelectric body 6 are rigidly joined together by, for example, brazing instead of the adhesive 7 in the ultrasonic vibrator 100 of the first embodiment. FIG. 9A shows the state of deformation due to a temperature change from normal temperature to high temperature, and FIG. 9B shows the state of deformation due to a temperature change from normal temperature to low temperature. Depending on the difference in the linear expansion coefficient between the stainless steel that forms the casing 4 and the piezoelectric ceramic of the piezoelectric body 6, the casing 4 is deformed into a convex shape, and thus, the piezoelectric body 6 receives a moment in a direction in which the spacing between the slits 101 is expanded in the high temperature state. In the low temperature state, the casing 4 is deformed into a concave shape, and thus, the piezoelectric body 6 receives a moment in a direction in which the spacing between the slits 101 is narrowed. These deformations are the forces that are exerted in the direction in which the piezoelectric body 6 is separated from the casing 4 and deforms the piezoelectric body 6 constructed of piezoelectric ceramic of a brittle material when the bonding power is strong. The transverse rupture strength of the piezoelectric ceramic is about 60 MPa to 100 MPa, and the amount of distortion in the case is about 300 ppm to 500 ppm. In the case of a temperature change of 50° C., a difference in the amount of distortion between the stainless steel and the piezoelectric ceramic is about 500 ppm, and a stress that exceeds the transverse rupture strength is generated in the vicinity of the bonded portion and the common portion in the vicinity of the terminal end of the slits 101, highly possibly causing the breakdown of the piezoelectric ceramic.

Therefore, it is necessary to use the adhesive 7 that has the function to reduce the difference in the linear expansion coefficient (linear expansion alleviating function) instead of rigid fixation in order to avoid the above phenomenon.

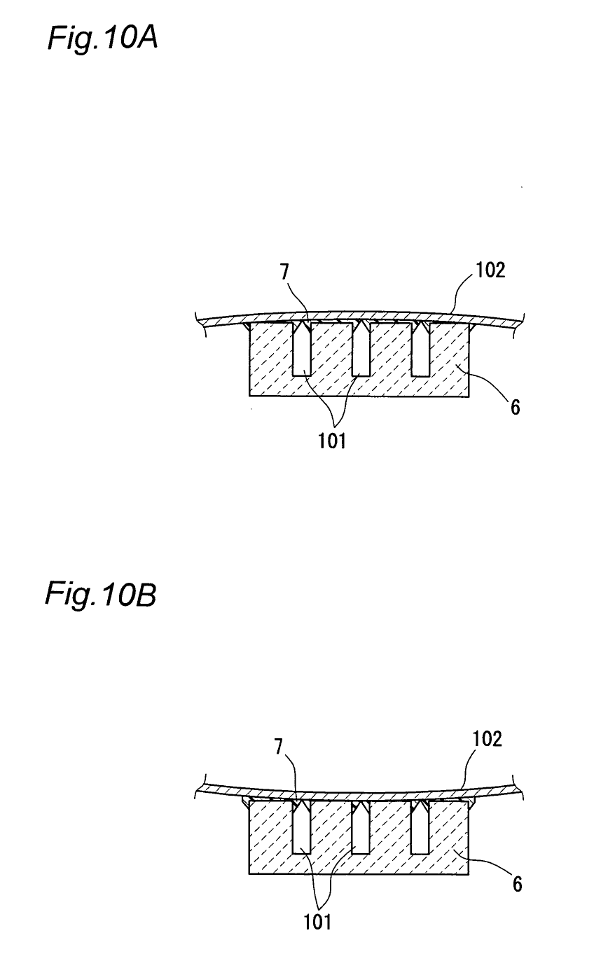

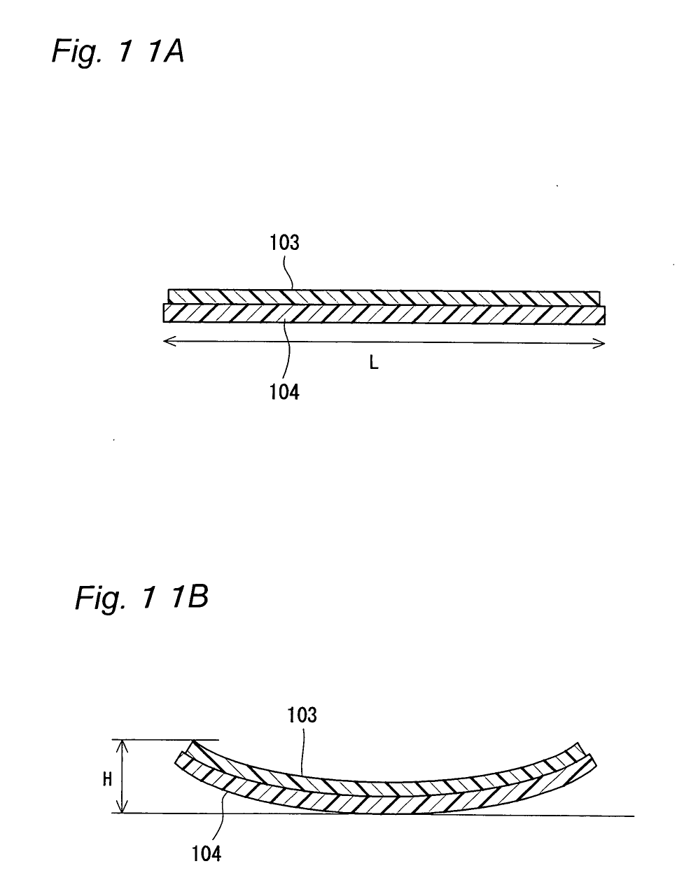

FIGS. 10A and 10B are schematic views showing the states of thermal deformation reduction by virtue of the deformation of the adhesive 7. FIG. 10A shows a state of temperature change from normal temperature to high temperature, and FIG. 10B shows a state of temperature change from normal temperature to low temperature. In FIGS. 10A and 10B, only a ceiling portion 102 represents the casing 4. As shown in FIGS. 10A and 10B, the deformation of the casing 4 of a great linear expansion coefficient is absorbed by the deformation of the adhesive 7, so that the generation of a stress in the piezoelectric body 6 of a small linear expansion coefficient is suppressed. That is, by using a material, which is softer than those of the casing 4 and the piezoelectric body 6, as the adhesive 7 so that the difference in the thermal deformation between the casing 4 and the piezoelectric body 6 can be absorbed, the ultrasonic vibrator 100 stable to the temperature change can be provided. Although the catalog data of the manufacturer can be referred to about the hardness of the adhesive 7, it is desirable to experimentally make and actually measure samples in consideration of the actual curing condition, bonding condition, and so on because the hardness changes depending on the curing condition and the bonding condition.

As a simple test for evaluating the hardness of a thin film of adhesive or the like, a pencil hardness test (JISK5600-5-4(1999)/ISO/DIS15184) for testing the hardness according to whether or not a line can be drawn with pencils of various hardnesses can be used. The adhesive 7 used in the first embodiment of the present invention optimally has hardness within a range of HB to 2B with respect to a pencil hardness range of H to 5B as a basis. In the case of pencil hardness harder than H, a warp when a thermal shock is received becomes excessively great, and it is not preferable. In the case of pencil hardness softer than 5B, there is a possibility that the adhesive strength becomes excessively small, and it is not preferable. Accordingly, particularly when the pencil hardness falls within the range of HB to 2B, the adhesive strength does not become excessively small, and the warp when a thermal shock is received is also small. Therefore, high reliability can be obtained during use over an extended period of time (e.g., for ten years at a minimum) in an outdoor environment where the temperature change is particularly great (the temperature change has a range of, for example, −30° C. to 60° C.), and it is more preferable.

### SELECTION TO RESIDUAL STRESS

Other points that should be considered when selecting the adhesive 7 includes the internal strain caused by the curing and the contraction of the adhesive 7. An internal stress is generated due to residual of the internal strain, and any deformation occurs in the piezoelectric body 6 and the casing 4 even in the state of normal temperature, reducing the stability to the temperature change. When thermosetting epoxy resin is used as the adhesive 7, the epoxy resin itself has a small contraction rate of not higher than 10% with curing as an adhesive. However, strain generally occurs and changes depending on the curing condition and the bonding condition. Therefore, it is desirable to experimentally make and actually measure samples in consideration of the actual curing condition, bonding condition, and so on. As the evaluation method, a method for applying an adhesive to a heat-resistant film, curing by heating the film, and evaluating the total amount of warp of the film can be used. FIGS. 11A and 11B are schematic views for explaining the evaluation method of the internal strain. In FIGS. 11A and 11B, the reference numeral 104 denotes a heat-resistant polymer film, and the numeral 103 denotes an adhesive for evaluating the internal strain. FIG. 11A shows a state in which the adhesive 103 before curing is applied to the heat-resistant polymer film 104, and FIG. 11B shows a state in which the adhesive 103 after curing by heating is applied to the heat-resistant polymer film 104. Since the adhesive 103 contracts by curing, a warp occurs in the polymer film 104, and the whole film sample is curved. This time, the adhesive to be evaluated was applied to a thickness of 80 μm onto almost the entire surface (in a rectangular shape of 60 mm×40 mm) of a polyimide sheet that had a rectangular shape of 70 mm×50 mm and a thickness of 130 μm and cured by heating. Subsequently, the height H of the warp occurred in the polyimide sheet was evaluated.

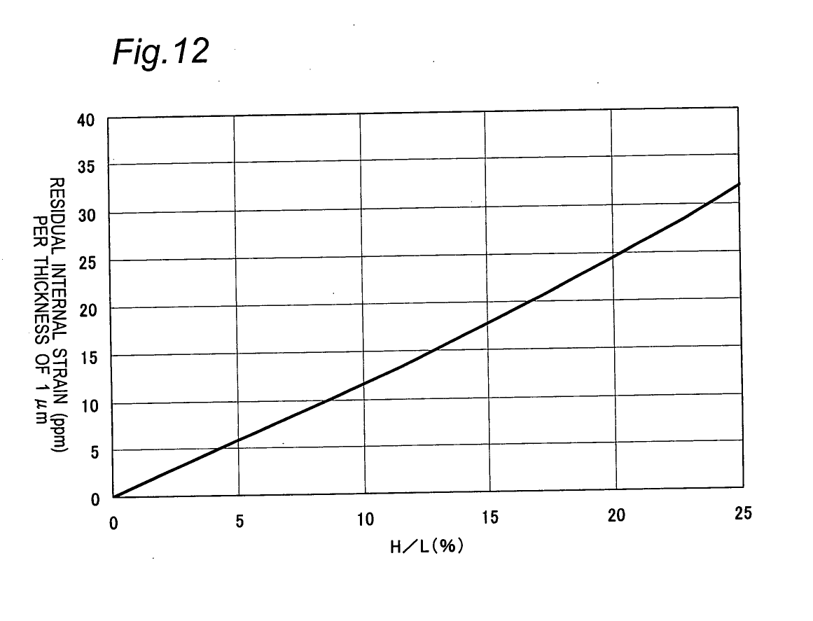

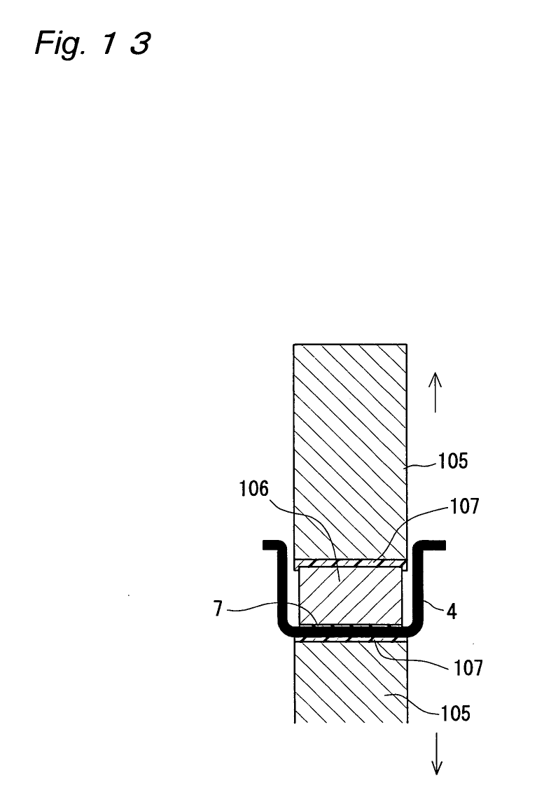

Assuming that the length of the sheet (length of the long side of the rectangular sheet) of the polymer film 104 is L and the height of the warp (height of the warp at an end portion with respect to the center portion of the sheet) is H, then the internal strain of the adhesive 103 can be presumed by obtaining the radius of curvature of the warp. FIG. 12 shows the conversion of the residual internal strain per 1 μm of the thickness of the corresponding adhesive obtained from the converted radius of curvature with respect to H/L on the lateral axis. The conversion of the radius of curvature is performed as follows. That is, assuming that the adhesive application surface of the heat-resistant polymer film 104 does not contract (neutral surface) and the radius of curvature is R, then the following equation holds, and the radius of curvature is obtained.
Cos(L/2R)=1−H/R
where H represents the height of the warp, and L represents the length in the lengthwise direction of the rectangle. Given that the thickness of the layer of the adhesive is T, the residual internal strain at the time is expressed as T/R.

According to FIG. 12, when the value of H/L is not smaller than 20%, the residual internal strain becomes about 250 ppm and almost reaches 300 ppm of the strain of the transverse rupture strength of the piezoelectric ceramic in the case where the layer of the adhesive is 10 μm. Therefore, it is preferable to select a material whose H/L is not greater than 10% or desirably not greater than approximately 5% for the adhesive 7. By selecting a material whose H/L is not greater than approximately 5%, high reliability can be obtained during use over an extended period of time (e.g., for ten years at a minimum) in an outdoor environment where the temperature change is particularly great (the temperature change has a range of, for example, −30° C. to 60° C.), and it is more preferable.

### ADHESIVE THICKNESS AND ADHESIVE STRENGTH

Furthermore, other points that should be considered when selecting the adhesive 7 include adhesive strength. The adhesive strength is related to securing the stability of the ultrasonic vibrator 100 over an extended period of time. At the same time, as a feature of the structure of the ultrasonic vibrator 100 in the first embodiment of the present invention, electric continuity to the grounding outer terminal 10b is secured via the casing 4 and the terminal plate 9 with partial electric continuity provided by controlling the state of bonding between the piezoelectric body 6 and the casing 4. Therefore, the adhesive 7 itself needs to produce a sufficient adhesive strength with the thickness of the surface roughness level of the casing 4 and the piezoelectric body 6. Moreover, as a secondary influence, the thickness of the adhesive 7 largely influences the transmission and reception characteristics of ultrasonic waves, which are the original functions of the ultrasonic vibrator 100. Therefore, the thickness of the adhesive 7 needs to be smaller than the sum of maximum heights Rz of the adhesion surfaces of the piezoelectric body 6 and the casing 4 or desirably is about the sum of average heights Ra.

In this case, the maximum height Rz is the maximum height provided by JIS B 0601-2001 and means a value obtained by extracting from a roughness curve by a sampling length in the direction of its average line, measuring an interval between the crest line and the bottom line of the extracted portion in a direction of the longitudinal magnification of the roughness curve, and expressing the value in micrometers (μm). The curve is extracted by the sampling length from a portion that has neither extraordinary high hill nor low hollow regarded as a flaw. In contrast to this, the average height Ra is the height of the arithmetic mean. When the roughness curve is extracted by the sampling length in the direction of its average line, and the roughness curve is expressed as y=f(x) with the x-axis taken in the direction of the average line of the extracted portion and the y-axis taken in the direction of the longitudinal magnification, the average height means a value expressed in micrometers (μm) obtained by the following equation:

$$Ra = \frac{1}{l} {\int }_{0}^{l} \vert f ( x ) \vert ⅆ x$$

For example, when the adhesion surface of the piezoelectric body 6 is subjected to abrasive finishing with a lap mesh of #1000, the maximum height is about 5 μm, and the average height is about 1 μm. The surface roughness of the casing 4 has the same level, and the thickness of the adhesive 7 should be not greater than 10 μm and desirably be about 2 to 3 μm.

In this case, whether or not a sufficient adhesive strength can be secured can be estimated from catalog data and so on. However, it is desirable to experimentally make and actually measure samples in consideration of the actual curing condition, bonding condition, and so on because the tension strength changes depending on the curing condition and the bonding condition. As a method for evaluating whether or not a sufficient adhesive strength can be secured, a tension test by means of a tension tester can be adopted.

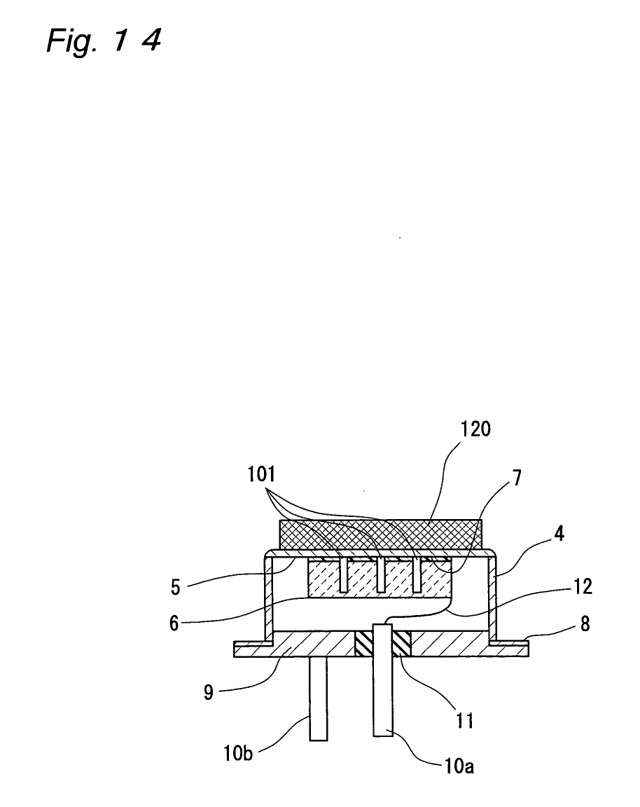

FIG. 13 is a schematic view of the sample for the tension test used this time. The reference numeral 105 denotes tension test jigs, 106 an aluminum block, and 107 another type adhesive. The sample is produced by bonding together the aluminum block 106 and the casing 4 with the adhesive 7 to be evaluated on the same bonding condition as that of the ultrasonic vibrator 100, further holding them between the tension test jigs 105, and bonding them with the stronger adhesive 107 from both sides. The produced sample was subjected to a tension tester and pulled by the tension test jigs 105 in the directions of arrows in FIG. 13. A tensile stress at a point of time when the separation of the adhesive 7 occurs between the aluminum block 106 and the casing 4 was measured, and the adhesive strength was evaluated. The adhesive strength basically ranges from 5 to 30 Mpa and properly is not smaller than 10 MPa. It is sufficient for the adhesive strength to be not smaller than 5 Mpa in normal uses. The pressure at the adhesive interface in the normal ultrasonic wave transmission stage is not greater than 1 MPa. However, if a temperature change of about 60° C. (e.g., 20° C. to 80° C.) is applied when the casing and the piezoelectric body are rigidly joined together without adhesive, a stress of not smaller than 10 MPa is generated through a thermal shock test. The adhesive reduces the occurrence of the stress, so that the stress actually becomes equal to or lower than 5 MPa. However, in consideration of the safety factor to durability, an adhesive strength of not smaller than 10 MPa is appropriate. Moreover, an adhesive of an excessively high adhesive strength is generally hard, and the effect of reducing the linear expansion coefficient might be reduced. Therefore, the strength is basically set not greater than 30 MPa.

### OTHER DESCRIPTIONS

Further, as another point that should be considered, there is a glass transition point Tg. The glass transition point Tg is measured by hardening a sample of a thickness of about 1.5 mm by a known thermomechanical analysis method or the like. The glass transition point Tg is basically set to 40° C. to 120° C. and optimally is within a range of 50° C. to 90° C. The above is because the characteristics of the sensor easily become unstable when the glass transition point Tg is lower than 40° C. In the case of a polymer material, the molecular structure becomes rubbery at a point of not lower than the glass transition point Tg. The polymer material in the rubbery state, which has a loss increased in the ultrasonic region, therefore is properly used in the glassy state not greater than the glass transition point Tg in consideration of the sensor characteristics. However, as in the ultrasonic transmitter-receiver of the present invention, which has a wide temperature range of use and is used particularly at high temperature, the durability is improved when the thermal deformation of each portion is reduced by using the rubbery region in the high temperature region. Conversely, one, which has a high glass transition point Tg and is hard even to high temperature, therefore has a small effect of reducing the linear expansion coefficient of the casing and the piezoelectric element and generally has high hardness. Therefore, the glass transition point Tg basically ranges from 40° C. to 120° C. and optimally ranges from 50° C. to 90° C.

Table 1 shows the results of evaluation of seven kinds of adhesives of A from F, ratios to the initial state of the reception voltage after carrying out a thermal shock test (test for applying temperatures of −40° C. and 85° C. each for 30 minutes) one hundred cycles, and ratios to the initial state of the electric capacity in order to select the adhesive 7 to be used in the first embodiment of the present invention.

TABLE 1

| | | | | | 100 Cycles of | |
|---|---|---|---|---|---|---|
| | | | | | Thermal Shock Test | |
| | | | | | (−40° C., 85° C. each | |
| | | Warp | | | for 30 min.) | |
| | | Test | | Adhesive | Reception | |
| | Pencil | H/L | Tg | Strength | Voltage | Capacity |
| Adhesive | Hardness | (%) | (° C.) | (MPa) | Ratio | Ratio |
| A | 2B | 3.7 | 50 | 9.9 | 1.00 | 1.01 |
| B | 2H | 7.5 | 124 | 12.5 | 0.89 | 0.96 |
| C | — | 15 | 124 | 16.7 | 0.93 | 0.97 |
| D | — | 2.5 | — | 13.4 | 0.96 | 0.95 |
| E | B | 0 | 59 | 11.1 | 1.01 | 1 |
| F | B | 2.5 | 72 | 14.3 | 0.11 | 0.22 |
| G | 2B | 0 | 43 | 10.5 | 0.93 | 0.92 |

With the adhesive E that exhibited a pencil hardness of B, almost zero percent of warp test, a glass transition point Tg of about 59° C., and an adhesive strength of 11.1 MPa, no deterioration was observed regarding both the reception voltage and the electric capacity even after 100 cycles of the thermal shock test causing neither separation between the casing 4 and the piezoelectric body 6 nor damage of the piezoelectric body 6, so that an ultrasonic vibrator excellent in durability was able to be provided.

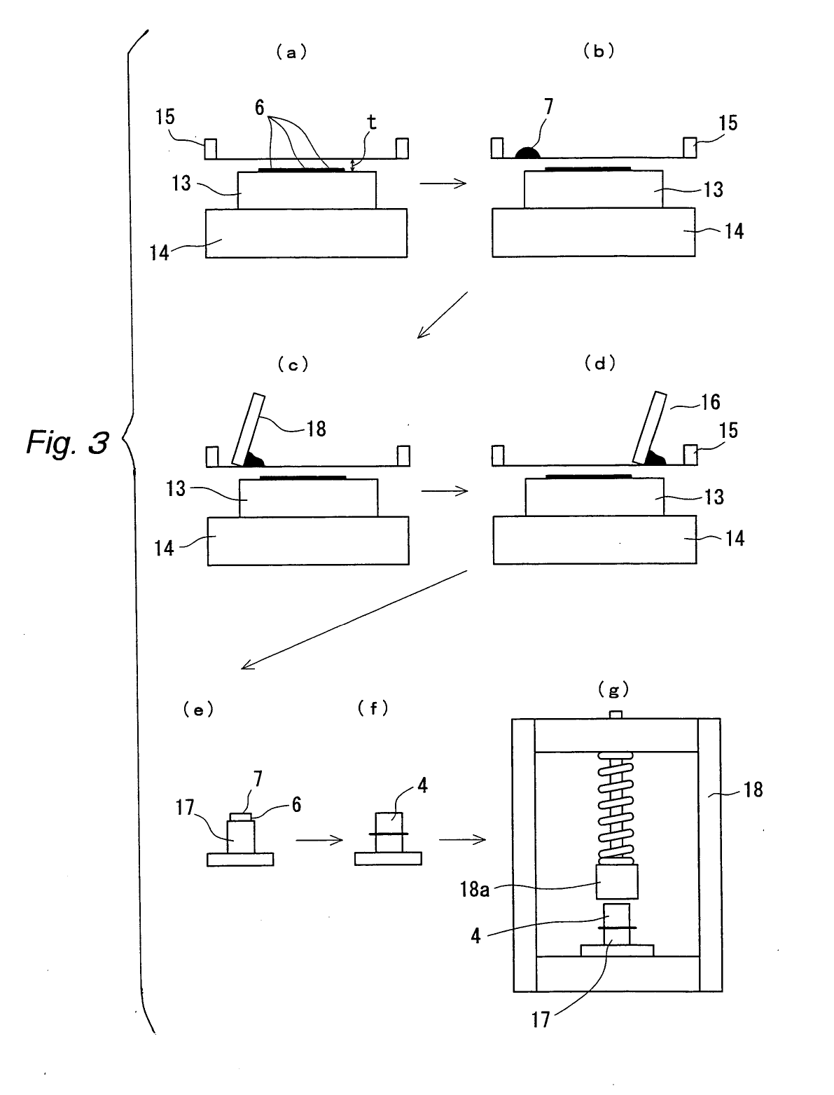

A method for forming the ultrasonic vibrator 100 of the first embodiment of the present invention is 15 described next with reference to FIGS. 3(a) through 3(g). As a method for applying the adhesive 7 to the adhesive application surface of the piezoelectric body 6, there can be enumerated, for example, a screen-printing method or a transfer method. The piezoelectric body 6 is placed on a piezoelectric body fixing jig 13. A difference in level of between the projecting piezoelectric body 6 and the piezoelectric body fixing jig 13 is basically 0 mm to 0.2 mm, and the piezoelectric body fixing jig 13 is designed so that the piezoelectric body 6 is placed higher by about 0.1 mm or a level difference adjusting plate (not shown) is provided. The piezoelectric body fixing jig 13 is fixed on a printing base 14, and a screen 15 is placed on it. At this time, a gap t that ranges from 0 mm to 1.5 mm is basically provided between the piezoelectric body 6 and the screen 15, and more preferably, a gap t of a value within a range of 0.3 mm to 0.8 mm, for example, about 0.5 mm is provided. The other portion of the screen 15 is masked so that the adhesive 7 is applied only to the adhesive application portion of the piezoelectric body 6. The aperture dimension of the screen 15 is basically made smaller than the adhesive application portion of the piezoelectric body 6 by 0 mm to 0.2 mm on one side or practically by, for example, about 0.1 mm. Next, as shown in FIG. 3(b), the adhesive 7 from which air has been removed by a deaerator (not shown) is placed on the screen 15. The adhesive 7 is applied by a squeegee 16. As shown in FIGS. 3(c) and 3(d), the squeegee 16 applies the adhesive 7 to the piezoelectric body 6 by being moved along the plane of the adhesive application portion of the piezoelectric body 6 while applying a certain load in the vertical direction to the piezoelectric body 6. The number of piezoelectric bodies 6 to which the adhesive 7 is applied at a time is one to about twenty five, and the number of piezoelectric bodies to which the adhesive 7 can be uniformly applied to a thickness within a range of 10 to 20 μm after application is selected. Next, as shown in FIG. 3(e), the piezoelectric body 6, to which the adhesive 7 is applied, is transported onto an adhesive curing jig 17. It is acceptable to use the piezoelectric body fixing jig 13 as a part of the adhesive curing jig 17. As shown in FIGS. 3(f) and 3(g), the casing 4 is placed on the surface of the piezoelectric body 6 to which the adhesive 7 has been applied, and a load is uniformly applied to the piezoelectric body 6 from above the casing 4 with a pressurizing member 18a of a pressurizing jig 18. For example, the load is applied by, for example, a known spring load type, and the adhesive 7 is cured under this condition. At the casing 4 and the piezoelectric body 6, which have been thus bonded with the adhesive 7, the electrode portion of the piezoelectric body 6 and the signal outer terminal 10a are connected to each other via the lead wire 12 with solder as shown in FIG. 1. The terminal plate 9 is fixed to the casing 4 by carrying out electric welding to the casing support portion 8 of the casing 4. By welding the casing 4 to the terminal plate 9, they serve as the ground of the electrode and concurrently play the role of sealing the piezoelectric body 6. At this time, by replacing air in a space, which is the space that accommodates the piezoelectric body 6 and is sealed between the casing 4 and the terminal plate 9, with a dried inert gas or the like, the electrode portion of the piezoelectric body 6 and the adhesive 7 can be prevented from deteriorating.

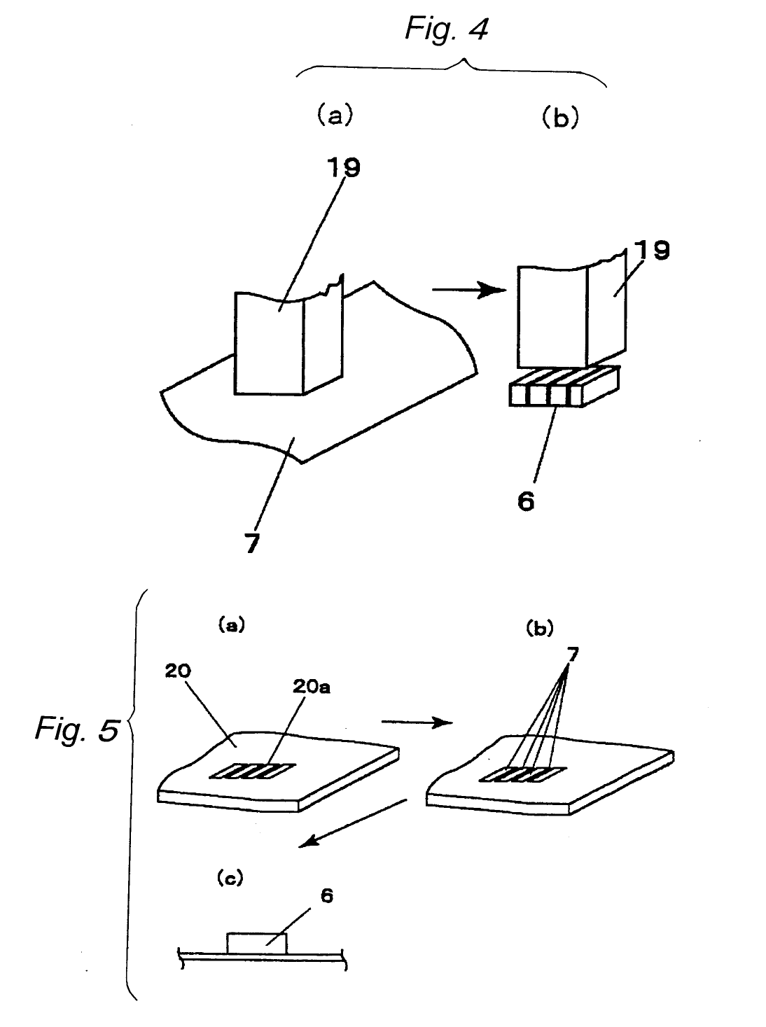

A transfer system as another means for applying the adhesive 7 to the piezoelectric body 6 is able to take a necessary amount of adhesive 7 to a transfer pin 19 by means of the transfer pin 19 from, for example, a portion where the thickness of the adhesive 7 is made uniform ranging from 10 to 20 μm, as shown in FIG. 4(a), and bring the transfer pin 19 in contact with the application surface of the piezoelectric body 6 as shown in FIG. 4(b) to apply the adhesive 7 to the application surface of the piezoelectric body 6. Moreover, instead of the above, it is also possible to process a polyimide plate 20 or the like for the formation of a recess portion 20a corresponding to the shape of transfer of the adhesive 7 as shown in FIG. 5(a), then bury the adhesive 7 into the recess portion 20a as shown in FIG. 5(b), and pressurize the piezoelectric body 6 on the recess portion 20a in which the adhesive 7 is buried as shown in FIG. 5(c) for the transfer of the adhesive 7 of the recess portion 20a to the adhesive application surface of the piezoelectric body 6.

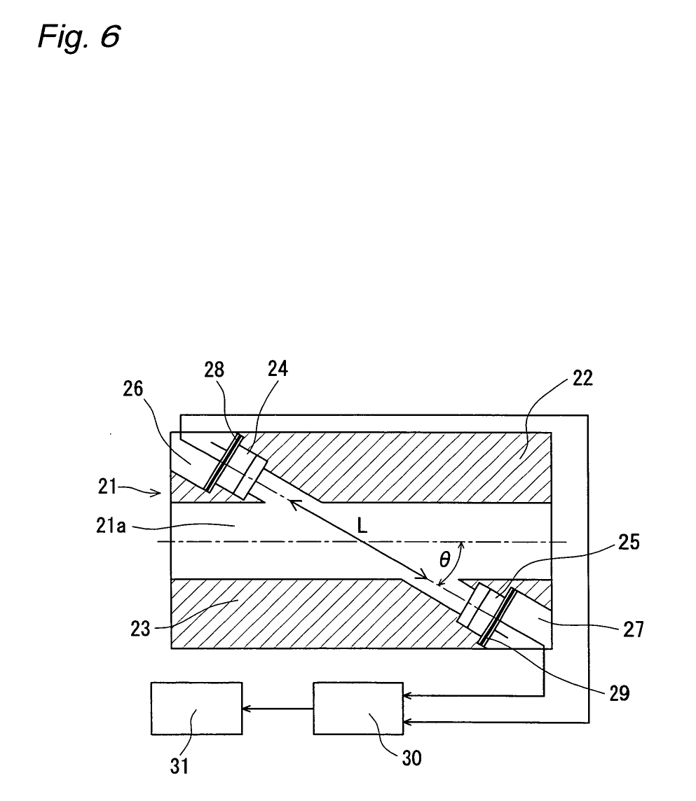

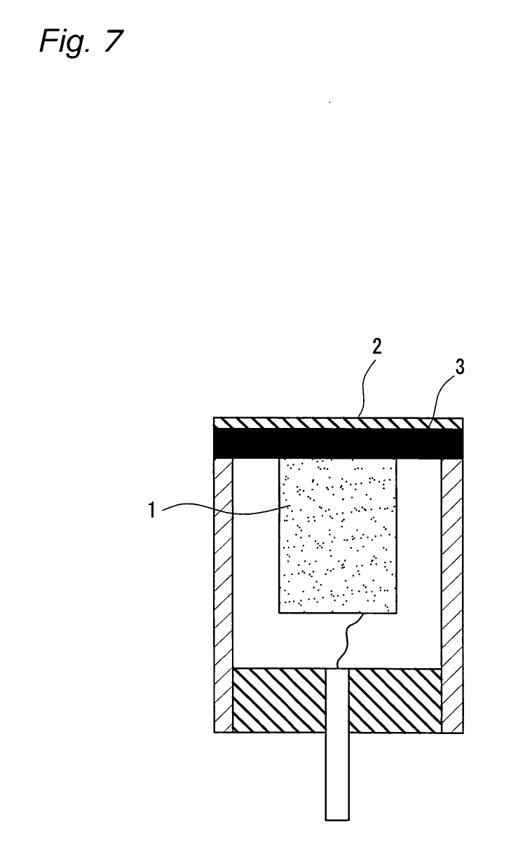

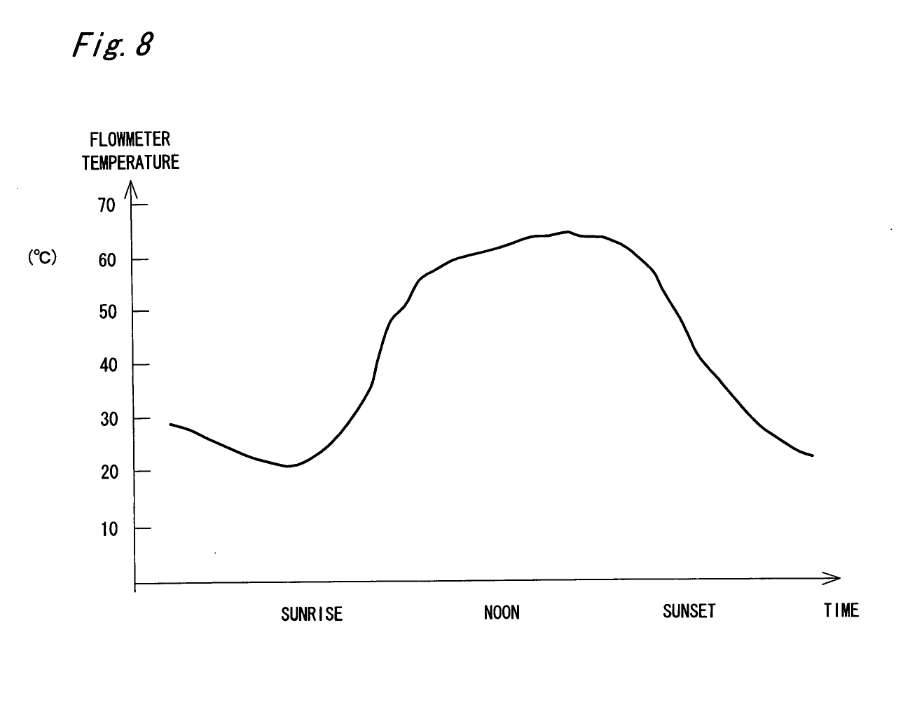

The ultrasonic flowmeter that employs the ultrasonic vibrator 100 formed as described above is described with reference to FIG. 6.

A flow rate measurement unit 21 for calculating and measuring the flow rate of the flowing fluid to be measured is provided with sidewall portions 22 and 23 that are formed into a circular or rectangular cylindrical shape so as to surround a passage 21a of the fluid to be measured. Ultrasonic vibrators 24 and 25 are fixed to vibrator mounting holes 26 and 27 provided obliquely to the sidewall portions 22 and 23 so that the transmission and reception wave fronts oppose to each other. Since the flow rates of a gas such as air, hydrogen or a flammable gas; or a liquid such as water, kerosene, or petroleum are assumed to be measured as the fluid to be measured, sealing members 28 and 29 are provided between the ultrasonic vibrators 24 and 25 and the vibrator mounting holes 26 and 27, respectively, so as to prevent the leak of the gas or liquid. For example, the known sing-around method is used as a measurement method. The reference numeral 30 denotes a measurement unit for measuring the propagation time of ultrasonic waves between the transmitter and receiver constituted of the ultrasonic vibrators 24 and 25, and the numeral 31 denotes a flow rate calculation part for calculating and obtaining the flow rate by carrying out correction and so on based on measurement results from the measurement unit 30.

The principle of measurement when the sing-around method is used is described more in detail below. First of all, when a driving burst voltage signal is applied to a first ultrasonic transmitter-receiver constructed of the ultrasonic vibrator 24 to radiate an ultrasonic burst signal from the first ultrasonic transmitter-receiver 24, the ultrasonic burst signal propagates through a propagation path of a distance L and reaches a second ultrasonic transmitter-receiver 25 constructed of the ultrasonic vibrator 25 after a lapse of a time t. The second ultrasonic transmitter-receiver 25 can convert only the propagating ultrasonic burst signal into an electric burst signal at a high signal-to-noise ratio. The electric burst signal is electrically amplified and applied again to the first ultrasonic transmitter-receiver 24, thus radiating an ultrasonic burst signal. Such a device is called the sing-around device, the time required for an ultrasonic pulse to radiate from the ultrasonic transmitter-receiver 24, propagate through the propagation path, and reach the ultrasonic transmitter-receiver 25 is called the sing-around period, and its reciprocal is called the sing-around frequency.

In FIG. 6, it is assumed that the flow velocity of the fluid that flows in a tubular passage 21a is V, the velocity of ultrasonic waves in the fluid is C, and an angle between the direction in which the fluid flows and the direction in which the ultrasonic pulse propagates is θ. Assuming that, when the first ultrasonic transmitter-receiver 24 is used as an ultrasonic transmitter and the second ultrasonic transmitter-receiver 25 is used as an ultrasonic receiver, the sing-around period that is the time required for the ultrasonic pulse emitted from the ultrasonic transmitter-receiver 24 to reach the ultrasonic transmitter-receiver 25 is t₁ and the sing-around frequency is f₁, then the following Equation (1) holds.
f₁=1/t₁=(C+Vcosθ)/L (1)

Conversely, assuming that, when the second ultrasonic transmitter-receiver 25 is used as an ultrasonic transmitter and the first ultrasonic transmitter-receiver 24 is used as an ultrasonic receiver, the sing-around period is t₂ and the sing-around frequency is f₂, then the following Equation (2) holds.
f₂=1/t₂=(C−Vcosθ)/L (2)

Therefore, a frequency difference Δf between both the sing-around frequencies is expressed by the following Equation (3), and the flow velocity V of the fluid can be obtained from the distance L of the propagation path of the ultrasonic waves and the frequency difference Δf.
θf=f₁=f₂=2Vcosθ/L (3)

That is, the flow velocity V of the fluid can be obtained from the distance L of the propagation path of the ultrasonic waves and the frequency difference Δf, and the flow rate measurement can be carried out by obtaining the flow rate from the flow velocity V by calculation.

Therefore, by employing the ultrasonic vibrators 24 and 25 excellent in reliability within the temperature range of outdoor use, there can be provided the ultrasonic flowmeter with durability in which the ultrasonic vibrators 24 and 25 are not damaged even when used outdoors over an extended period of time.

It is noted that the casing 4, which has the lidded cylindrical shape in the first embodiment, may be provided by a flat plate or a flat portion of the outer wall of the flow rate measurement unit 21. Moreover, the casing 4, which is made of the material of stainless steel, may be made of a metal of aluminum, aluminum die casting, or the like.

### SECOND EMBODIMENT

FIG. 14 shows a sectional view of the ultrasonic vibrator of the second embodiment of the present invention.

In FIG. 14, the reference numeral 120 denotes an acoustic matching layer that establishes acoustic matching with the objective fluid to be measured to increase the efficiency of the ultrasonic vibrator. The other construction is the same as that of the first embodiment.

The material of the acoustic matching layer 120 is selected according to the objective fluid to be measured, and when the fluid is a liquid, epoxy resin in which various fillers are incorporated, an inorganic material of glass, graphite, or the like can be used. When the fluid is air, a town gas, or the like, the acoustic matching layer 120 can be formed of a composite material in which hollow glass spheres are solidified with a resin based material or an inorganic/organic porous material. The acoustic matching layer 120 is to establish acoustic matching of the objective fluid to be measured with the piezoelectric body 6 that oscillates ultrasonic waves and is designed so as to satisfy the following Expression (4) assuming that the acoustic impedance of the piezoelectric body 6 is Z₁, the acoustic impedance of the objective fluid to be measured is Z₂, and the acoustic impedance of the acoustic matching layer 102 is Z₃.
Z₁>Z₃>Z₂ (4)

Moreover, with a thickness design of a quarter wavelength with respect to the frequency of the ultrasonic waves oscillated by the piezoelectric body 6, the efficiency of the transmission and reception of ultrasonic waves can be increased.

When the acoustic matching layer 120 is provided, it is necessary to consider the linear expansion coefficient of the acoustic matching layer 120. Particularly, when a resin material or a composite material in which various fillers are incorporated is used for the acoustic matching layer 120, deformation due to the temperature change might be further expanded because its linear expansion coefficient is generally greater than that of the stainless steel material of the casing 4. However, with adhesive selection and the manufacturing method of the piezoelectric body 6 and the casing 4 similar to those of the first embodiment, a sensor, which endures thermal shocks, can be constituted. An ultrasonic vibrator using the composite material of epoxy resin in which minute hollow glass spheres were incorporated was experimentally produced as the acoustic matching layer 120. The adhesive E in Table 1 was selected for the piezoelectric body 6 and the casing 4 as in the first embodiment. Moreover, the acoustic matching layer 120 and the casing 4 were experimentally produced with the adhesive B in Table 1. The experimentally produced ultrasonic vibrator was subjected to the thermal shock test (test for applying temperatures of −40° C. and 85° C. each for 30 minutes), and consequently neither reduction in the reception voltage nor change in the electric capacity was measured even after one hundred cycles of the test.

As described above, by appropriately selecting the adhesive 7 for bonding the piezoelectric body 6 to the casing 4, the ultrasonic vibrator, which operated with stability with respect to the temperature change even in the presence of the acoustic matching layer 102, is able to be provided, and an increase in the transmission and reception efficiency is achieved by virtue of the additionally provided acoustic matching layer 102. The ultrasonic flowmeter, which employs the present ultrasonic vibrator, is improved in the signal-to-noise ratio and therefore has a higher accuracy and excellent temperature stability.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

### INDUSTRIAL APPLICABILITY

As described above, the ultrasonic vibrator of the present invention and the ultrasonic flowmeter that employs the vibrator are able to prevent the separation of the bonded portion of the piezoelectric body and the adherend fixation body and the damage of the piezoelectric body due to the thermal shock test. Therefore, the ultrasonic vibrator can be used over an extended period of time even in outdoor environments and also applicable to the uses of gas meters for measuring the flow rates of town gas or LP gas, water meters for measuring the volume of water of a water service, flow rate measurement devices of hydrogen or fuel gas of fuel cells, range sensors used for automobiles, and so on.

1-11. (canceled)

12. An outdoor-use ultrasonic flowmeter comprising:
a flow rate measurement unit for measuring a flow rate of a flowing fluid to be measured;
a pair of ultrasonic vibrators, provided at the flow rate measurement unit for transmitting and receiving ultrasonic waves to and from the fluid to be measured;
a measurement unit for measuring a propagation time between the pair of ultrasonic vibrators; and
a flow rate calculation part calculating the flow rate of the fluid to be measured on a basis of a signal from the measurement unit, wherein each of the ultrasonic vibrators comprises:
a piezoelectric body;
an adherend fixation body constituted by a metallic lidded cylindrical casing having a ceiling portion and a sidewall portion; and
an adhesive having a linear expansion reducing function to expand and contract permit expansion and contraction so as to reduce a difference in linear expansion coefficient between the piezoelectric body and the adherend fixation body, wherein one surface of the piezoelectric body is fixedly surface-bonded to an inner wall surface of the ceiling portion of the adherend fixation body with the adhesive, the adhesive is comprised of a layer having an average thickness of 2 to 3 μm. and the adhesive has a glass transition point of 40° C. to 120° C.

13. The outdoor-use ultrasonic flowmeter as claimed in claim 12, wherein the adhesive has a pencil hardness of H to 5B by a pencil hardness test.

14. The outdoor-use ultrasonic flowmeter as claimed in claim 13, wherein the adhesive has an adhesive strength of 5 to 30 MPa.

15. The outdoor-use ultrasonic flowmeter as claimed in claim 14, wherein the adhesive has a height dimension ratio of not greater than approximately 5% of a warp of an end portion with respect to a center portion of a the adhesive formed applied in a rectangular shape relative to a length of a long side when the adhesive is formed applied in the rectangular shape.

16-19. (canceled)

20. The outdoor-use ultrasonic flowmeter as claimed in claim 12, wherein the piezoelectric body has a slit formed along a thickness direction of the inner wall surface of the ceiling portion of the adherend fixation body to which the piezoelectric body is fixed.

21. The outdoor-use ultrasonic flowmeter as claimed in claim 12, wherein the vibrator further comprises a terminal plate fixed to an open end of the lidded casing, and
the lidded casing and the terminal plate seal the piezoelectric body.

22. (canceled)
